(19) United States
(12) Patent Application Publication
(10) Pub. No.: US 2026/0005023 A1
(43) Pub. Date: Jan. 1, 2026

(54) METHODS FOR FABRICATING SEMICONDUCTOR DEVICES AND RESIST COMPOSITIONS FOR UNDERLAYERS USED THEREFOR

(71) Applicant: Samsung Electronics Co., Ltd., Suwon-si (KR)

(72) Inventors: Sang hyun Je, Suwon-si (KR); Joo sung Lee, Suwon-si (KR)

(21) Appl. No.: 19/179,338

(22) Filed: Apr. 15, 2025

(30) Foreign Application Priority Data
Jun. 5, 2024 (KR) 10-2024-0073752

(51) Int. Cl. H01L 21/027; G03F 7/004; G03F 7/027; G03F 7/11; G03F 7/16

(52) U.S. Cl. CPC H01L 21/0274; G03F 7/0045; G03F 7/0048; G03F 7/027; G03F 7/11; G03F 7/168

(57) ABSTRACT

A method for fabricating a semiconductor device, includes forming an underlayer on a feature layer, forming a photoresist layer on the underlayer, exposing a first region of the photoresist layer, forming a photoresist pattern by removing a second region of the photoresist layer using a developer while retaining the first region of the photoresist layer, and processing the underlayer and the feature layer using the photoresist pattern, where each of the underlayer and the photoresist layer includes at least one of a benzooxazine monomer or a polymer produced by polymerizing the benzooxazine monomer.

### CROSS-REFERENCE TO RELATED APPLICATION

This application claims priority under 35 U.S.C. § 119 to Korean Patent Application No. 10-2024-0073752 filed on Jun. 5, 2024, in the Korean Intellectual Property Office, the disclosure of which is incorporated by reference herein in its entirety.

### FIELD

Embodiments of the present disclosure described herein relate to a method for fabricating a semiconductor device, and more particularly, relate to a resist composition for an underlayer used therefor.

### BACKGROUND

Recently, as electron technology has developed, smaller-sized semiconductor devices have been rapidly developed. To realize semiconductor devices in a smaller size, photolithography processes have been required to form a fine pattern.

The photolithography process may include an exposure process and a development process. The exposure process may include inducing a chemical change in structure of a resist layer by irradiating light having a specific wavelength to the resist layer. The exposure process may include selectively removing an exposed part or a non-exposed part using the difference in solubility between the exposed part and the non-exposed part of the resist layer.

However, residues may be produced from the resist layer during the exposure process and the development process, thereby caused defects. Accordingly, there is a need for the development of a technology to resolve the issue.

### SUMMARY

Embodiments of the present disclosure provide a method for fabricating a semiconductor device, capable of reducing or preventing defects resulting from the residues of a resist layer during a photolithography process.

Embodiments of the present disclosure provide a resist composition for an underlayer used for a method for fabricating a semiconductor device.

According to an embodiment, a method for fabricating a semiconductor device comprises forming an underlayer on a feature layer, forming a photoresist layer on the underlayer, exposing a first region of the photoresist layer, removing a second region except for the first region of the photoresist layer using a developer to form a photoresist pattern, and processing the underlayer and the feature layer using the photoresist pattern. Each of the underlayer and the photoresist layer includes at least one of a benzooxazine monomer, or a polymer produced by polymerizing the benzooxazine monomer.

According to an embodiment of the present disclosure, a resist composition for an underlayer includes a benzooxazine monomer expressed as in Chemical Formula 1, and a solvent,

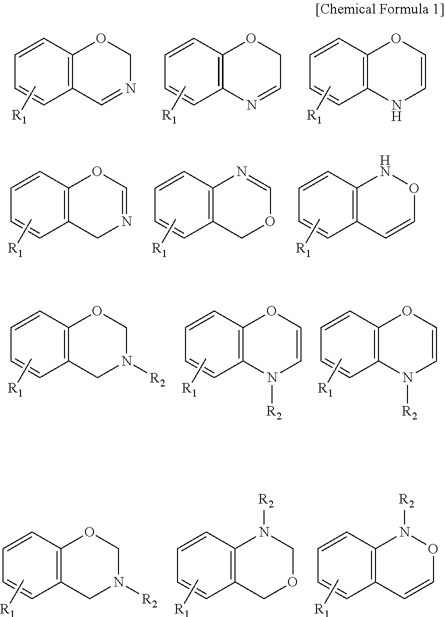

in which R₁ is at least one of a hydrogen atom, a substituted or unsubstituted monovalent hydrocarbon having 1 to 20 carbon atoms, a halogen atom, or a protecting group including an acid-labile reactor, and R₂ is a hydrogen atom, or a substituted or unsubstituted monovalent hydrocarbon having 1 to 20 carbon atoms.

### BRIEF DESCRIPTION OF THE FIGURES

The above and other objects and features of the present disclosure will become apparent by describing in detail embodiments thereof with reference to the accompanying drawings.

FIG. 1 is a flowchart illustrating a method for fabricating an integrated circuit device according to an embodiment of the present disclosure; and

FIGS. 2A to 2E are cross-sectional views illustrating a method for fabricating an integrated circuit device in a process sequence according to an embodiment of the present disclosure.

### DETAILED DESCRIPTION

While the present disclosure is susceptible to various modifications and alternative forms, specific embodiments thereof are shown by way of example in the drawings and will be described herein in detail. It should be understood, however, that there is no intent to limit the present disclosure to the particular forms disclosed, but on the contrary, the present disclosure is to cover all modifications, equivalents, and alternatives falling within the spirit and scope of the inventive concept.

Embodiments of the present disclosure described herein relate to a method for forming a pattern through a photolithography process, and a resist composition for an underlayer used therefor. According to an embodiment, the method for forming the pattern through the photolithography process may be employed for a method for fabricating a semiconductor device. Hereinafter, the method for fabricating the semiconductor device will be described instead.

According to an embodiment of the present disclosure, the resist composition includes a benzooxazine monomer. The benzooxazine monomer may be polymerized by heat and/or light and used for an underlayer in the photolithography process. In addition, the benzooxazine monomer may be polymerized by light and used as a negative photoresist.

Hereinafter, a composition including the benzooxazine monomer will be collectively referred to as a “resist composition”, which will be described before the description about a process for fabricating the semiconductor device using the resist composition.

According to an embodiment of the present disclosure, the resist composition includes a benzooxazine monomer and a solvent. The benzooxazine monomer is a monomer polymerized by heat and/or light.

The benzooxazine monomer may be at least one of the compounds of Chemical Formula 1.

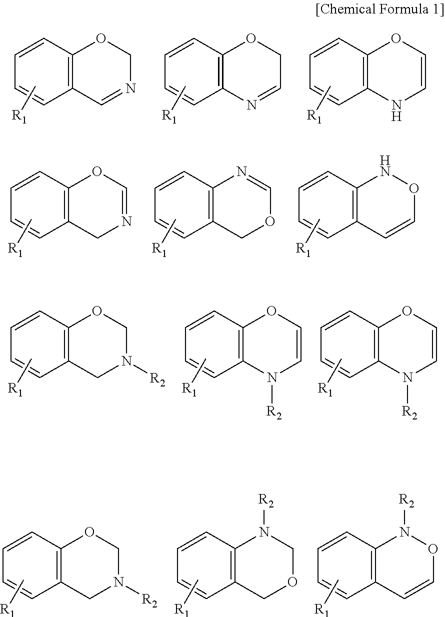

wherein, R₁ is at least one of a hydrogen atom, a substituted or unsubstituted monovalent hydrocarbon having 1 to 20 carbon atoms, a halogen atom, or a protecting group including an acid-labile reactor, and R₂ is a hydrogen atom, or a substituted or unsubstituted monovalent hydrocarbon group having 1 to 20 carbon atoms. In some embodiments, the halogen atom may be one Cl, Br, or I.

R₁ and/or R₂ may be, for example, a monovalent chain hydrocarbon having 1 to 20 carbon atoms, a monovalent alicyclic hydrocarbon having 3 to 20 carbon atoms, a monovalent aromatic hydrocarbon having 6 to 20 carbon atoms, or a combination thereof.

The ‘hydrocarbon’ includes a chain hydrocarbon, an alicyclic hydrocarbon, and an aromatic hydrocarbon. The ‘hydrocarbon’ includes a saturated hydrocarbon and an unsaturated hydrocarbon. The term ‘chain hydrocarbon’ refers to a hydrocarbon including only a chain structure without a ring structure, and includes both a linear-chain hydrocarbon and a branched-chain hydrocarbon. The term ‘alicyclic hydrocarbon’ refers to a hydrocarbon having a ring structure having no aromatic ring structure, and includes both a single ring alicyclic hydrocarbon and a multi-ring alicyclic hydrocarbon (the alicyclic hydrocarbon needs not have only an alicyclic structure, and may partially have a chain structure). The term ‘aromatic hydrocarbon’ refers to a hydrocarbon having a ring structure including an aromatic ring structure (in which the aromatic hydrocarbon needs not to have only an aromatic ring structure, and may partially include an alicyclic structure or a chain structure).

For example, the monovalent chain hydrocarbon having 1 to 20 carbon atoms may include an alkyl, such as a methyl, an ethyl, an n-propyl, an i-propyl, an n-butyl, a sec-butyl, and a tert-butyl, an alkenyl, such as an ethenyl, a propenyl, and a butenyl, or an alkynyl, such as an ethynyl, a propynyl, and a butynyl.

For example, the monovalent alicyclic hydrocarbon having 3 to 20 carbon atoms may include a cycloalkyl, such as a cyclopentyl and a cyclohexyl, a cycloalkenyl, such as a cyclopropenyl, a cyclopentenyl, and a cyclohexenyl, a crosslinked saturated hydrocarbon, such as a norbornyl, an adamantyl, and a tricyclodecenyl; and a crosslinked unsaturated hydrocarbon, such as a norbornenyl and a tricyclodecenyl.

For example, the monovalent aromatic hydrocarbon having 6 to 20 carbon atoms may include a phenyl, a tolyl, a naphthyl, an anthracenyl, and a pyrenyl.

When R₁ and/or R₂ have a substituent, the substituent may be a monovalent chain hydrocarbon having 1 to 10 carbon atoms, a halogen atom, such as a fluorine atom, a chlorine atom, a bromine atom, and an iodine atom, an alkoxy, such as a methoxy, an ethoxy, and a propoxy, an alkoxycarbonyl, such as a methoxycarbonyl and an ethoxycarbonyl, an alkoxycarbonyloxy, such as a methoxycarbonyloxy and an ethoxycarbonyloxy, an acyl, such as a formyl, an acetyl, a propionyl, or a butyryl, a cyano, a nitro, and a hydroxyl.

According to an embodiment of the present disclosure, R₁ and/or R₂ may be a hydrogen atom or a methyl.

Each of R₁ and/or R₂ independently may have the structure as in Chemical Formula 2. In the following Chemical Formula 2, ‘*’ is an attaching position (e.g., binding site).

*-L-Ar [Chemical Formula 2]

wherein, L refers to a single bond or a divalent linker, and Ar refers to a monovalent group having an aromatic ring having 6 to 20 of ring forming atoms. The term “the number of ring-forming atoms” refers to the number of atoms forming a ring structure. For example, the number of ring-forming atoms in a biphenyl ring is 12, the number of ring-forming atoms in a naphthalene ring is 10, and the number of ring-forming atoms in a fluorine ring is 13.

In some embodiments, L may be a single bond, an alkanediyl excluding one hydrogen atom from an alkyl having 1 to 10 carbon atoms, a cycloalkylene excluding one hydrogen atom from a cycloalkyl having 5 to 10 carbon atoms, a carbonyl, an oxygen atom, or a combination thereof.

In addition, Ar may be, for example, an aromatic hydrocarbon, such as benzene, naphthalene, anthracene, indene, or pyrene, an aromatic heterocyclic ring, such as pyridine, pyrazine, pyrimidine, pyridazine, triazine, or any combination thereof.

According to an embodiment of the present disclosure, Ar may be at least one of the functional groups represented by the following Chemical Formula 3.

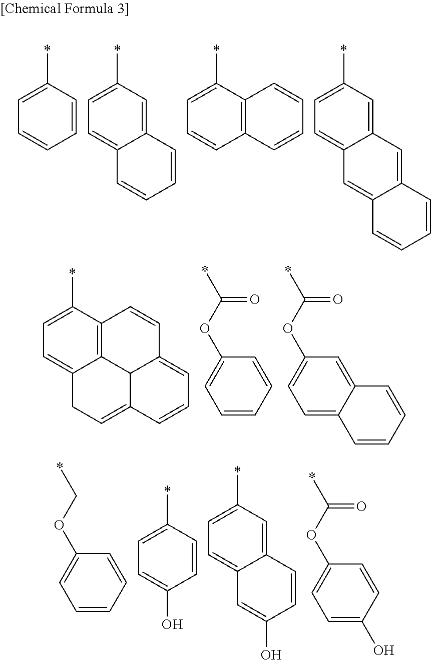

An acid-labile reactor of the protecting group may be decomposed by employing the acid, which is generated in the exposure step of the photolithography process, as a catalyst. Accordingly, the protecting group may be deprotected under an acid catalyst. In addition, the deprotected protecting group may produce new acid to perform a chemical amplification action.

The protecting group may be attached to an acid-labile reactor such as an ester. The protecting group may be substituted or unsubstituted, and may be an alkyl having 1 to 10 carbon atoms, a haloalkyl having 1 to 10 carbon atoms, an aryl having 6 to 18 carbon atoms, a haloaryl, an arylalkyl having 7 to 18 carbon atoms, an alkylaryl having 7 to 18 carbon atoms, or a haloaryl having 6 to 18 carbon atoms. According to one embodiment, the protecting group may be an alkyl in a linear-chain structure, a branched structure, or a cyclic structure having 1 to 6 carbon atoms, a vinyloxyethyl, tetrahydropyranyl, a tetrafuranyl, a trialkylsilyl, isonobonyl, 2-methyl-2-adamantyl, 2-ethyl-2-adamantyl, 3-tetrahydrofuranyl, 3-oxoxyclohexyl, γ-butyllactone-3-yl, mavaloniclactone, γ-butyrolactone-2-yl, 3-methyl-γ-butyrolactone-3-yl, 2-tetrahydropyranyl, 2-tetrahydrofuranyl, 2,3-propylenecarbonate-1-yl, 1-methoxyethyl, 1-ethoxyethyl, 1-(2-methoxyethoxy)ethyl, 1-(2-acetoxyethoxy)ethyl, t-buthoxycarbonylmethyl, methoxymethyl, ethoxymethyl, trimethoxysilyl, triethoxysilyl, a methoxyethyl, an ethoxyethyl, an n-propoxyethyl, an isopropoxyethyl, an n-butoxyethyl, an isobutoxyethyl, a tert-butoxyethyl, a cyclohexyloxyethyl, a methoxypropyl, an ethoxypropyl, a 1-methoxy-1-methyl-ethyl, a 1-ethoxy-1-methylethyl, a tert-butoxycarbonyl (t-BOC), or a tert-butoxycarbonyl methyl. In addition, the alkyl in the linear-chain structure or the branched structure may include a methyl, an ethyl, a propyl, an isopropyl, an n-butyl, an isobutyl, a tert-butyl, a pentyl, an isopentyl, or a neopentyl. Further, the alkyl in the cyclic structure may include a cyclopentyl, or a cyclohexyl.

According to an embodiment of the present disclosure, one type of benzooxazine monomer may be used in the resist composition, or a plurality of types of benzooxazine monomer may be used together in the resist composition. The benzooxazine monomer may be at least a portion of the repeating units constituting a benzooxazine polymer.

In the resist composition according to an embodiment of the present disclosure, the benzooxazine monomer may be included in content ranging from about 40 wt % to about 95 wt % or any range therein, for example, ranging from about 45 wt % to about 90 wt %, or ranging from about 50 wt % to about 90 wt %, based on the total weight of the resist composition.

According to an embodiment of the present disclosure, the benzooxazine monomer may be polymerized by heat and/or light. The benzooxazine monomer may be thermally polymerized and/or photopolymerized to form layers having different uses when fabricating a semiconductor device. The details thereof will be described below.

The following Chemical Reaction 1 exemplifies the thermal polymerization reaction of a benzooxazine monomer. In Chemical Rection 1, for convenience of explanation, a reaction formula is shown for 2H-1,4-benzooxazine among the benzooxazine monomers shown in Chemical Formula 1.

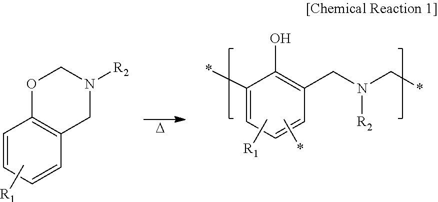

The resist composition may further include a crosslinker for enhancing crosslinking properties during polymerization (especially during thermal polymerization). When a crosslinker is used and the benzooxazine monomer is thermally polymerized, the physical property of the polymerized benzooxazine-based polymer may be varied depending on the presence of the crosslinker, the type of crosslinker, and the content of the crosslinker. In particular, the etch rate of the benzooxazine-based polymer may be varied depending on the presence of the crosslinker, the type of crosslinker, and the content of the crosslinker

The crosslinker may be at least one selected from polyfunctional (meth)acrylates, cyclic ether-containing compounds, glycolurils, diisocyanates, melamines, benzoguanamines, polynuclear phenols, polyfunctional thiol compounds, polysulfide compounds, and sulfide compounds, but the present disclosure is not limited thereto.

The polyfunctional (meth)acrylates are not particularly limited as long as the polyfunctional (meth)acrylates are compounds having at least two (meth)acryloyl groups. For example, polyfunctional (meth)acrylate obtained by allowing an aliphatic polyhydroxy compound to react with (meth)acrylic acid, caprolactone-modified polyfunctional (meth)acrylate, alkylene oxide-modified polyfunctional (meth)acrylate, polyfunctional urethane (meth)acrylate obtained by allowing (meth)acrylate having a hydroxyl to react with polyfunctional isocyanate, or polyfunctional (meth)acrylate having a carboxyl obtained by allowing (meth)acrylate having a hydroxyl to react with an acid anhydride may be included.

Specifically, for example, the polyfunctional (meth)acrylates may include trimethylolpropane tri(meth)acrylate, ditrimethylolpropane tetra(meth)acrylate, pentaerythritol tri(meth)acrylate, pentaerythritol tetra(meth)acrylate, dipentaerythritolpenta (meth)acrylate, dipentaerythritolhexa (meth)acrylate, glycerin tri(meth)acrylate, tris(2-hydroxyethyl) isocyanurate tree(meth)acrylate, ethylene glycol di(meth)acrylate, 1,3-butanediol di(meth)acrylate, 1,4-butanediol di(meth)acrylate, 1,6-hexanedioldi(meth)acrylate, neopentyl glycol di(meth)acrylate, diethylene glycol di(meth)acrylate, triethylene glycol di(meth)acrylate, dipropylene glycol di(meth)acrylate, or bis(2-hydroxyethyl) isocyanurate di(meth)acrylate.

For example, the cyclic ether-containing compounds may be oxylanyl-containing compounds including 1,6-hexanedioldiglycidyl ether, 3′,4′-epoxyclohexenylmethyl-3′,4′-epoxyclohexene carboxylate, or vinylcyclohexene monooxide 1,2-epoxy-4-vinylcyclohexene, or 1,2:8,9-diepoxylimonene, or oxetanyl-containing compounds including 3-ethyl-3-hydroxymethyloxetane, 2-ethylhexyl oxetane, xilylene bis oxetane, or 3-ethyl-3 {[(3-ethyl oxctane-3-yl)methoxy]methyl}oxetane. The cyclic ether-containing compounds may include individually oxylanyl-containing compounds or oxetanyl-containing compounds or may include a combination of at least two compounds of oxylanyl-containing compounds or oxetanyl-containing compounds.

The glycolurils may be, for example, tetramethylol glycoluril, tetramethoxy glycoluril, tetramethoxymethyl glycoluril, compounds modified through methoxymethylation of 1 to 4 methylols of tetramethylol glycoluril or the mixture thereof, compounds modified through acyloxymethylation of 1 to 4 methylol groups of tetramethylol glycoluril, or glycidyl glycoluril.

For example, glycidyl glycoluril may be 1-glycidyl glycoluril, 1,3-diglycidyl glycoluril, 1,4-diglycidyl glycoluril, 1,6-diglycidyl glycoluril, 1,3,4-triglyceridyl glycoluril, 1,3,4,6-tetraglycidyl glycoluril, 1-glycidyl-3a-methylglycoleuryl, 1-glycidyl-6a-methylglycoluril, 1,3-diglycidyl-3a-methylglycoluril, 1,4-diglycidyl-3a-methylglycoluril, 1,6-diglycidyl-3a-methylglycoluril, 1,3,4-triglycidyl-3a-methylglycoluril, 1,3,4-triglycidyl-6a-methylglycoluril, 1,3,4,6-tetraglycidyl-3a-methylglycoluryl, 1-glycidyl-3a,6a-dimethylglycoluryl, 1,3-diglycidyl-3a,6a-dimethylglycoluryl, 1,4-diglycidyl-3a,6a-dimethylglycoluryl, 1,6-diglycidyl-3a,6a-dimethylglycoleuril, 1,3,4-triglycidyl-3a,6a-dimethylglycoleuril, 1,3,4,6-tetra-glycidyl-3a,6a-dimethylglycoleuril, 1-glycidyl-3a,6a-diphenylglycoleuril, 1,3-diglycidyl-3a,6a-diphenylglycoluryl, 1,4-diglycidyl-3a,6a-diphenylglycoluryl, 1,6diglycidyl-3a,6a-diphenylglycoluryl, 1,3,4-triglyceridyl-3a,6a-diphenylglycolouryl, or 1,3,4,6-tetraglycidyl-3a,6a-diphenylglycolouryl. The glycolurils may be used individually or in a combination of at least two types of glycolurils.

For example, diisocyanates may be 2,3-toluene diisocyanate, 2,4-toluene diisocyanate, 3,4-toluene diisocyanate, 3,5-toluene diisocyanate, 4,4′-diphenylmethane diisocyanate, hexamethylene diisocyanate, or 1,4-cyclohexane diisocyanate.

The melamines may include, for example, melamine, monomethylolmelamine, dimethylolmelamine, trimethylolmelamine, tetramethylolmelamine, pentamethylolmelamine, hexamethylolmelamine, monobutylolmelamine, dibutylolmelamine, tributylolmelamine, tetrabutylolmelamine, pentabutylolmelamine, hexabutylolmelamine, or alkylation derivatives of these methylolmelamines or butylolmelamines. The melamines may be used individually or used in a combination of at least two types of melamines.

Benzoguanamines include, for example, benzoguanamines in which amino groups are modified with four alkoxymethyl groups and/or alkoxymethylol groups); benzoguanamine in which amino groups are modified with the total of four groups of alkoxymethyl groups (especially, methoxymethyl groups) and/or hydroxymethyl groups (methylol groups); benzoguanamine in which amino groups are modified with at least three alkoxymethyl groups (especially, methoxymethyl groups); benzoguanamine in which amino groups are modified with a total of up to three groups of alkoxymethyl groups (especially methoxymethyl groups) and/or hydroxymethyl groups. For example, the benzoguanamines may include tetramethoxymethylbenzoguanamine. The melamines may be used individually or used in a combination of at least two types of melamines.

For example, polynuclear phenols may include dinuclear phenols, such as 4,4′-biphenyldiol, 4,4′-methylene bisphenol, 4,4′-ethylidene bisphenol, bisphenol A; trinuclear phenol, such as 4,4′,4″-methylenebisphenol, 4,4′-(1-(4-(4-hydroxyphenyl)-1-methylethyl)phenyl)ethylidene)bisphenol, or 4,4′-(1-(4-(4-hydroxy-3,5-bis(methoxymethyl)phenyl)-1-methylethyl)phenyl)ethylidene)bis(2,6-bis(methoxymethyl) phenol); and polyphenol, such as novolak. The polynuclear phenols may be used individually or used in a combination of at least two types of polynuclear phenols.

The polyfunctional thiol compound, which is a compound having at least two mercapto groups in one molecule, may, specifically, include compounds having two mercapto groups, such as 1,2-ethanedithiol, 1,3-propanedithiol, 1,4-butanedithiol, 2,3-butanedithiol, 1,5-pentanedithiol, 1,6-hexanedithiol, 1,8-octanedithiol, 1,9-nonanedithiol, 2,3-dimercapto-1-propanol, dithioerythritol, 2,3-dimercaptosuccinic acid, 1,2-benzenedithiol, 1,2-benzenedimethanethiol, 1,3-benzenedithiol, 1,3-benzenedimethanethiol, 1,4-benzenedimethanethiol, 3,4-dimercaptotoluene, 4-chloro-1,3-benzenedithiol, 2,4,6-trimethyl-1,3-benzenedimethanethiol, 4,4′-thiodiphenol, 2-hexylamino-4,6-dimercapto-1,3,5-triazine, 2-diethylamino-4,6-dimercapto-1,3,5-triazine, 2-cyclohexylamino-4,6-dimercapto-1,3,5-triazine, 2-di-n-butylamino-4,6-dimercapto-1,3,5-triazine, ethylene glycol bis(3-mercaptopropionate), butanediol bisthioglycolate, ethylene glycol bisthioglycolate, 2,5-dimercapto-1,3,4-thiadiazole, 2,2′-(ethylenedithio)diethanethiol, 2,2-bis(2-hydroxy-3-mercaptopropoxyphenylpropane), compounds having three mercaptos, such as 1,2,6-hexanetriol trithioglycolate, 1,3,5-trithiocyanuric acid, trimethylolpropane tris (3-mercaptopropionate), trimethylolpropane tristhioglycolate, or compounds having at least four mercapto groups, such as pentaerythritol tetrakis (2-mercaptoacetate), pentaerythritol tetrakis (2-mercaptopropionate) pentaerythritol tetrakis (3-mercaptopropionate), pentaerythritol tetrakis (3-mercaptobutyrate), 1,3,5-tris(3-mercaptobutyryloxyethyl)-1,3,5-triazine-2,4,6 (1H,3H,5H)-trione. The polyfunctional thiol compound may be used individually or used in a combination of at least two types of the polyfunctional thiol compounds.

According to an embodiment of the present disclosure, when the resist composition includes a crosslinker, the content of the crosslinker may range from 1 part (wt parts) by weight to 60 wt parts, or any range therein, for example, from 2 wt parts to 50 wt parts, or from 3 wt parts to 40 wt parts, based on 100 wt parts of benzooxazine monomer.

As described above, the benzooxazine monomer may be polymerized by light. Chemical Rection 2 expresses the photopolymerization reaction of an exemplary benzooxazine monomer. In Chemical Reaction 2, for convenience of explanation, a reaction formula is shown for 2H-1,4-benzooxazine among the benzooxazine monomers shown in Chemical Formula 1.

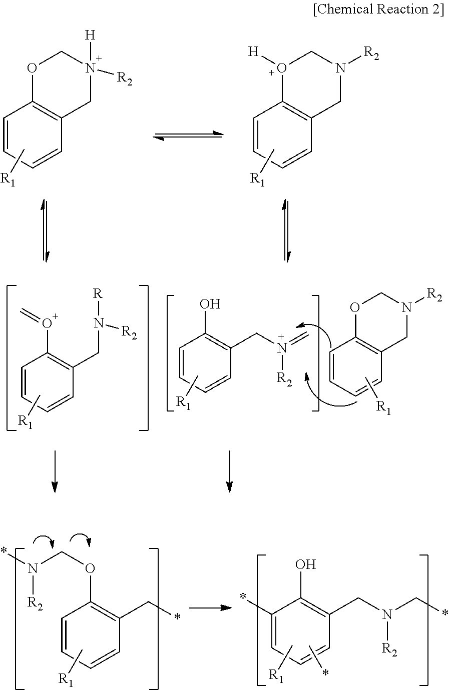

According to an embodiment, the resist composition may further include a photoacid generator, and the acid catalyst in Chemical Reaction 2 may be derived from the photoacid generator.

The photoacid generator, which is exposed to light to generate acid, may generate the acid when the photoacid generator is exposed by light having an ultraviolet wavelength band, especially, extreme ultraviolet (EUV) wavelength band. The light having the EUV wavelength band may be light selected from among a KrF excimer laser beam (248 nm), an ArF excimer laser beam (193 nm), an F2 excimer laser beam (157 nm), and an EUV laser beam (135 nm). The photoacid generator may include a material exposed to light to generate stronger acid having a pKa (an acid-labile constant) ranging from about −20 to about less than 1, or any range therein.

The photoacid generator may include, for example, triarylsulfonium salts, diaryliodonium salts, sulfonates or the mixture thereof. The photoacid generator may include at least one of triphenylsulfonium triflate, triphenylsulfonium antimonate, triphenylsulfonium difluoroalkyl sulfonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS or any combination thereof.

According to an embodiment of the present disclosure, in the resist composition, the photoacid generator may be included in content ranging from about 0.01 wt % to about 60.0 wt %, or any range therein, for example, ranging from about 0.05 wt % to about 55 wt %, or ranging from about 0.1 wt % to about 50 wt %.

According to an embodiment of the present disclosure, when the benzooxazine monomer is photopolymerized under acid catalyst, at least a portion of the benzooxazine monomer of Formula 1 may have an acid-labile protecting group as R₁. In the process in which the benzooxazine monomer is exposed to light to be polymerized, the protecting group deprotected by the acid-labile reactor may generate new acid to perform a chemical amplification action.

The solvent included in the resist composition may include an organic solvent. The organic solvent may include at least one of ether, alcohol, glycol ether, an aromatic hydrocarbon compound, ketone, or ester, but the present disclosure is not limited thereto. For example, the organic solvent include ethylene glycol monomethyl ether, ethylene glycol monoethyl ether, 2-methoxyethanol acetate, 2-ethoxyethanol acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbion: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or any combination thereof. The organic solvent may be used individually or in the form of a combination of at least two types of the above materials.

According to an embodiment of the present disclosure, the resist composition may include the solvent in a remaining content except for the content of main components such as benzooxazine monomer and the photoacid generator.

According to an embodiment of the present disclosure, the resist composition may include an additional component without degrading the effect of the present disclosure. When the resist composition includes additional components (e.g., crosslinkers, base quenchers, or surfactants), the additional component may be included in the remaining content except for the content of the main component and the different additional component. According to some embodiments, the solvent may be included in content ranging from about 0.1 wt % to about 99.7 wt %, or any range therein, based on the total weight of the resist composition.

According to an embodiment of the present disclosure, the resist composition may further include a base quencher.

The base quencher may trap acid in the non-exposed region when the acid generated from the photoacid generator is diffused into the non-exposed region of the resist layer included in the resist composition. According to an embodiment of the present disclosure, the base quencher is included in the resist composition, to prevent the acid, which is generated from the exposed region of the photoresist layer, from being diffused into the non-exposed region of the photoresist layer, after the photoresist layer obtained from the resist composition is exposed.

According to some embodiments, the base quencher may include primary aliphatic amine, secondary aliphatic amine, tertiary aliphatic amine, aromatic amine, heterocyclic ring-containing amine, a nitrogen-containing compound having a carboxyl, a nitrogen-containing compound having a sulfonyl, a nitrogen-containing compound having a hydroxyl, a nitrogen-containing compound having a hydroxyphenyl, an alcoholicnitrogen-containing compound, amides, imides, carbamates, or ammonium salts. For example, the base quencher may include triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or any combination thereof, but the present disclosure is not limited thereto.

According to some embodiments, the base quencher may include a photo-labile base. The photo-labile base may include a compound exposed by light to generate acid or to neutralize acid before exposed by light. In some embodiments, when the photo-labile base is exposed by light to be dissociated, the photo-labile base may not trap the acid. Accordingly, when a partial region of the photoresist layer formed based on a chemical-amplification resist composition including the base quencher including the photo-labile base is exposed by light, the photo-labile base loses alkalinity in the exposed region of the photoresist layer, and traps acid in the non-exposed region of the photoresist layer, thereby preventing the acid, which is generated in the exposed region of the photoresist layer, from being diffused to the non-exposed region of the photoresist layer.

The photo-labile base may include a carboxylate salt or a sulfonate salt of a photo-labile cation. For example, the photo-labile cation may form a complex with an anion of a carboxylic acid having 1 to 20 carbon atoms. The carboxylic acid may be, for example, formic acid, acetic acid, propionic acid, tartaric acid, succinic acid, cyclohexylcarboxylic acid, benzoic acid, or salicylic acid, but the present disclosure is not limited thereto.

According to an embodiment of the present disclosure, the resist composition may include the base quencher in the content ranging from about 0.01 wt % to about 5.0 wt %, or any range therein, but the present disclosure is not limited thereto.

According to some embodiments, the resist composition according to an embodiment of the present disclosure may further include at least one selected from the group consisting of a surfactant, a dispersant, an absorbent, and a coupling agent which are additional components.

The surfactant may improve coating uniformity of the resist composition and improve the wettability. According to some embodiments, the surfactant may include a sulfuric acid ester salt, a sulfonate salt, phosphoric acid ester, a soap, an amine salt, a quaternary ammonium salt, a polyethylene glycol, an alkylphenol ethylene oxide adduct, a polyhydric alcohol, a nitrogen-containing vinyl polymer, or any combination thereof, but the present disclosure is not limited thereto. For example, the surfactant may be selected from among a fluoroalkyl benzene sulfonate, a fluoroalkyl carboxylate, fluoroalkyl polyoxyethylene ether, fluoroalkyl ammonium iodide, fluoroalkyl betaine, a fluoroalkyl sulfonate, diglycerin tetrakis (fluoroalkyl polyoxyethylene ether), a fluoroalkyl trimethyl ammonium salt, a fluoroalkyl amino sulfonate, polyoxyethylene nonyl phenyl ether, polyoxyethylene octyl phenyl ether, polyoxyethylene alkyl ether, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene lauryl amine, sorbitan laurate, sorbitan palmitate, sorbitan stearate, sorbitan oleate, sorbitan fatty acid ester, polyoxyethylene sorbitan laurate, polyoxyethylene sorbitan palmitate, polyoxyethylene sorbitan stearate, polyoxyethylene sorbitan oleate, polyoxyethylene naphthyl ether, alkyl benzene sulfonate, and alkyl diphenyl ether disulfonate, but the present disclosure is not limited thereto. The surfactant may be included in content ranging about 0.001 wt % to about 0.1 wt %, or any range therein, based on the total weight of the chemical amplification resist composition, but the present disclosure is not limited thereto.

The dispersant may allow components constituting the resist composition to be uniformly dispersed in the resist composition. According to some embodiments, the dispersant may include epoxy resin, polyvinyl alcohol, polyvinyl butyral, polyvinyl pyrrolidone, glucose, sodium dodecyl sulfate, sodium citrate, oleic acid, linoleic acid, or any combination thereof, but the present disclosure is not limited thereto. When the resist composition includes the dispersant, the dispersant may be included in the content ranging from about 0.001 wt % to about 5 wt %, or any range therein, based on the total weight of the resist composition.

The absorbent may prevent an adverse influence by moisture included in the resist composition. For example, the absorbent may prevent metal, which may be included in the resist composition, from being oxidized by the moisture. According to some embodiments, the absorbent may include polyoxyethylene nonylphenol ether, polyethylene glycol, polypropylene glycol, polyacrylamide, or any combination thereof, but the present disclosure is not limited thereto. When the resist composition includes the absorbent, the absorbent may be included in the content ranging from about 0.001 wt % to about 10 wt %, or any range therein, based on the total weight of the resist composition.

The coupling agent may improve the adhesion to the underlayer, when the resist composition is coated onto the underlayer. According to some embodiments, the coupling agent may include a silane coupling agent. The silane coupling agent may include vinyltrimethoxysilane, vinyltriethoxysilane, vinyltrichlorosilane, vinyltris(β-methoxyethoxy) silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy [3-(phenylamino) propyl]silane. When the resist composition includes the coupling agent, the coupling agent may be included in the content ranging from about 0.001 wt % to about 5 wt %, or any range therein, based on the total weight of the resist composition.

According to an embodiment of the present disclosure, the resist composition may further include water, when the solvent includes only an organic solvent in the resist composition. In this case, the resist composition may include water included in the content ranging from about 0.001 wt % to about 0.1 wt %, or any range therein, based on the total weight of the resist composition.

As described above, according to an embodiment, the underlayer and the photoresist layer may be formed through thermal polymerization and/or photopolymerization using the benzooxazine monomer. In some embodiments, as the benzooxazine monomer has a pendant group such as R₁ and/or R₂ the pendant group attached to the benzooxazine monomer can be used in the thermal polymerization and/or the photopolymerization reaction. According to an embodiment of the present disclosure, as the underlayer and the photoresist layer include the same material-based compound, such as the benzooxazine compound, the adhesion between the underlayer and the photoresist layer is improved. In particular, according to an embodiment, when the underlayer and/or an above layer are formed, and when the crosslinker is included, the adhesion between the underlayer and the photoresist layer may be improved by the crosslinker.

In addition, according to an embodiment of the present disclosure, the benzooxazine monomer in a part, which is not exposed by light, of the photoresist layer has higher solubility for the developer, thereby preventing or reducing the defects caused by residues after the development process. In particular, the benzooxazine monomer in the part, which is not exposed by light, of the photoresist layer is mainly provided in the form of a monomolecular molecule. Accordingly, the benzooxazine monomer in the part which is not exposed by light is easily dissolved in the developer, and is not left as a residue.

The resist composition described above according to the present disclosure may be used, for example, when an integrated circuit device is fabricated.

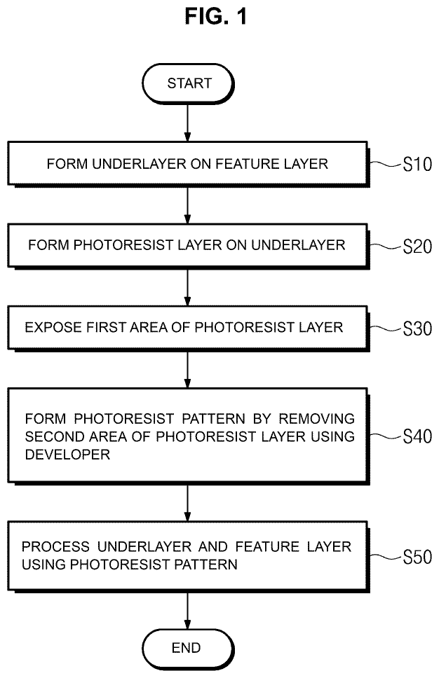

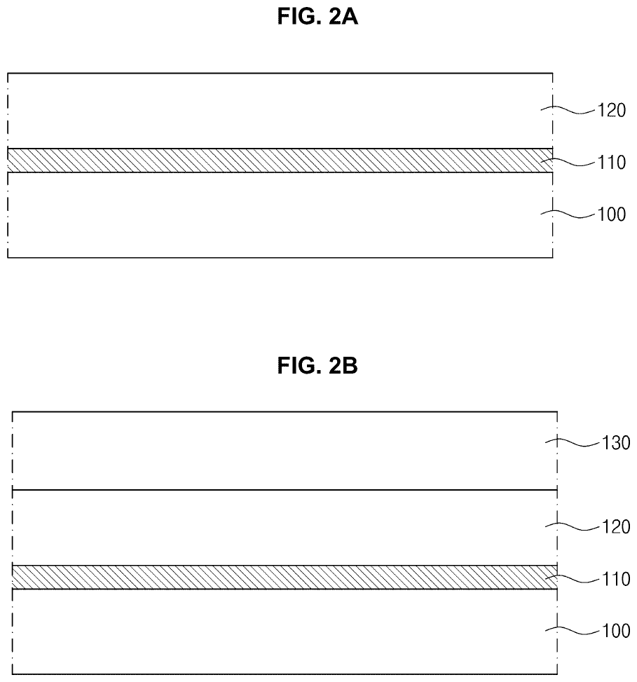

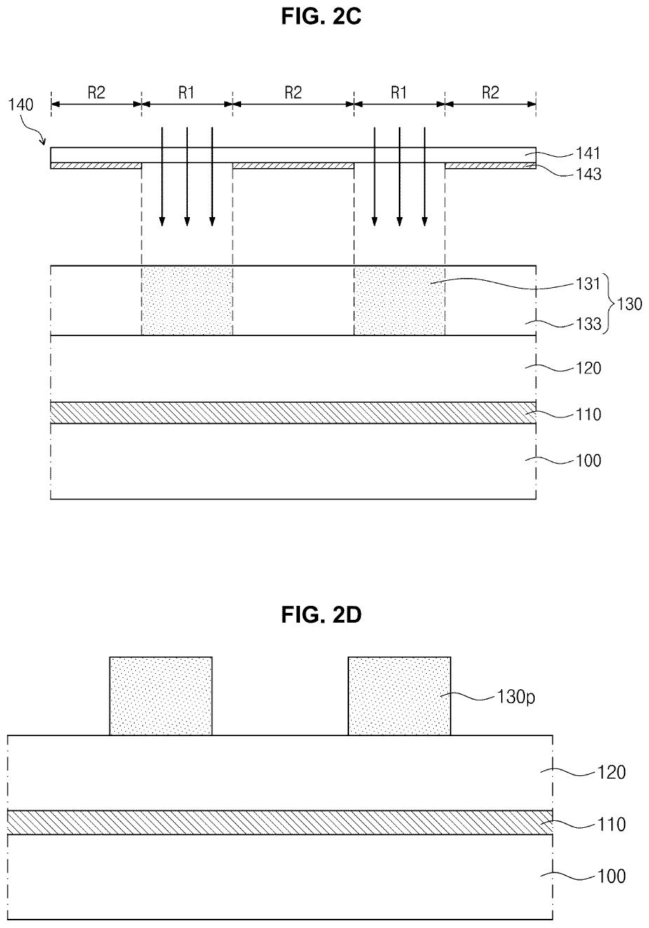

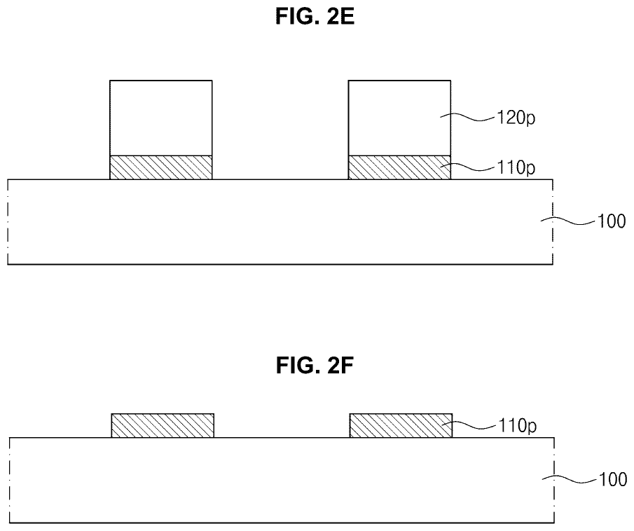

FIG. 1 is a flowchart illustrating a method for fabricating an integrated circuit device according to an embodiment of the present disclosure, and FIGS. 2A to 2E are cross-sectional views illustrating a method for fabricating an integrated circuit device in a process sequence according to an embodiment of the present disclosure.

According to an embodiment of the present disclosure, the integrated circuit device may be fabricated by forming an underlayer on a feature layer (S10), forming a photoresist layer on the underlayer (S20), exposing a first region of the photoresist layer (S30), forming a photoresist pattern by removing a second region of the photoresist layer using a developer (S40), and processing the underlayer and the feature layer using the photoresist pattern (S50). The details thereof will be described with reference to accompanying drawings.

Referring to FIGS. 1 and 2A, an underlayer 120 is formed on a feature layer 110.

The feature layer 110 may be a target layer to form a specific pattern in a final stage. A substrate 100 may be provided under the feature layer 110. The substrate 100 may include an atomic semiconductor material, such as Si or Ge, or a compound semiconductor material, such as SiGe, SiC, GaAs, InAs, or InP. However, the material of the substrate 100 is not limited thereto. For example, the substrate 100 may include various materials, as long as the substrate 100 serves as a base of the feature layer 110. For example, the substrate 100 may include various materials, such as metal, glass, or a polymer resin.

The feature layer 110 may be an insulating layer, a conductive layer, or a semiconductor layer. For example, the feature layer 110 may include metal, an alloy, a metal carbide, a metal nitride, a metal oxynitride, a metal oxycarbide, a semiconductor, polysilicon, an oxide, a nitride, an oxynitride, or any combination thereof, but the present disclosure is not limited thereto. A bottom anti-reflective coating (BARC) may be formed on the feature layer 110. In this case, the underlayer 120 may be formed on the BARC layer. The BARC layer may control scattered-reflection of light from a light source used in the exposure process to fabricate the integrated circuit device, or may absorb light reflected from the feature layer 110 under the BARC layer. According to an embodiment, the BARC layer may include an organic anti-reflective coating BARC material for a KrF excimer laser, an ArF excimer laser, or a different arbitrary light source. According to an embodiment, the BARC layer may include an organic ingredient having a light absorbing structure. The light absorbing structure may be a hydrocarbon compound having, for example, at least one benzene ring, or a structure in which benzene rings are fused. The BARC layer may be formed to have the thickness of about 5 nm to about 100 nm, or any range therein, but the present disclosure is not limited thereto. According to embodiments, the BARC layer may be omitted.

The underlayer 120 may be formed by coating the first resist composition including the benzooxazine monomer onto the feature layer 110, and performing an annealing process for the coated first resist composition. The coating manner may include a spin coating manner, a spray coating manner, a dip coating manner, or an aerosol coating manner.

The temperature for the annealing process may be equal to or higher than a temperature when the benzooxazine monomer is subject to the polymerization reaction. For example, the first resist composition may be subject to the annealing process at the temperature ranging from about 80° C. to about 150° C., or any range therein, for the time ranging from about 50 seconds to about 10 minutes, or any time range therein. However, the temperature for the annealing process for the first resist composition is not limited thereto.

In this case, the first resist composition may include at least one of benzooxazine monomers of Chemical Formula 1 and a solvent. However, in Chemical Formula 1, R₁ and R₂ may be any one of the above-described reactors, but does not need to be a protecting group including an acid-labile reactor (e.g., may be devoid of a protecting group including an acid-labile reactor). In other words, R₁ is at least one of a hydrogen atom, a substituted or unsubstituted monovalent hydrocarbon having 1 to 20 carbon atoms, or a halogen atom, and R₂ is a hydrogen atom, or a substituted or unsubstituted monovalent hydrocarbon having 1 to 20 carbon atoms.

According to an embodiment, the first resist composition may selectively further include at least one crosslinker. The crosslinker may include the above-described materials to enhance the crosslinking of the benzooxazine monomer in thermal polymerization. In addition, when the crosslinker is employed in thermally polymerizing the benzooxazine monomer, the physical property of matter may vary depending on the presence of the crosslinker, the type of the crosslinker, and the content of the crosslinker. In addition, the first resist composition may selectively further include other, additional, components (e.g., a surfactant, a dispersant, an absorbent, and a coupling agent).

As described above, the first resist composition for the underlayer 120 may be polymerized through thermal curing. However, an embodiment of the present disclosure is not limited thereto. For example, the first resist composition may be polymerized through photo-curing, or may be polymerized through both thermal-curing and photo-curing. The first resist composition for the underlayer 120 may be selectively cured and/or photocured to the extent of making the difference in etch rate from a photoresist layer 130 to be described later. When the underlayer 120 is formed through the polymerization reaction, the first resist composition may further selectively include a photoacid generator.

According to an embodiment of the present disclosure, the first resist composition may selectively further include a surfactant, a dispersant, an absorbent, and a coupling agent.

Referring to FIGS. 1 and 2B, the photoresist layer 130 is formed on the underlayer 120.

The photoresist layer 130 may be formed by coating a second resist composition including the benzooxazine monomer on the underlayer 120. The coating may be performed through a coating manner such as a spin coating manner, a spray coating manner, a dip coating manner, or an aerosol coating manner.

The second resist composition may include at least one of benzooxazine monomers in Chemical Formula 1 and a solvent. The second resist composition may further selectively include a crosslinker described above. The second resist composition may further include a photoacid generator to cause a polymerization reaction to occur under an acid catalyst.

In addition, the benzooxazine monomer of the second resist composition may have a protecting group including an acid-labile reactor, which differs from the first resist composition. In other words, in Chemical Formula 1, R₁, which has an acid-labile property, is at least one of a hydrogen atom, a substituted or unsubstituted monovalent hydrocarbon having 1 to 20 carbon atoms, a halogen atom, or a protecting group including an acid-labile reactor, and R₂ is a hydrogen atom, or a substituted or unsubstituted monovalent hydrocarbon having 1 to 20 carbon atoms.

According to an embodiment, the second resist composition may selectively further include a base quencher, a surfactant, a dispersant, an absorbent, and a coupling agent. In particular, the second resist composition may further include a base quencher. The base quencher may prevent acid, which is generated from the photoacid generator, from being diffused to the non-exposed region of the resist layer, or may reduce the acid when the benzooxazine monomer is exposed to light to be polymerized.

Referring to FIGS. 1 and 2C, the exposure process may be performed on the photoresist layer 130. The exposure process may include aligning a photomask 140 on the photoresist layer 130, and irradiating light to the photoresist layer 130 through the photomask 140.

The light may be in an ultra-violet wavelength band, especially, an extreme ultraviolet (EUV) wavelength band. The light in the EUV wavelength band may be any one selected from among a KrF excimer laser beam (of 248 nm), an ArF excimer laser beam (of 193 nm), an F2 excimer laser beam (of 157 nm), and an EUV laser beam (of 13.5 nm)

The photomask 140 may include a transparent substrate 141 and a plurality of light shielding patterns 143 formed in a plurality of light shielding regions on the transparent substrate 141. The transparent substrate 141 may include quartz. The plurality of light shielding patterns 143 may include chromium (Cr), but the present disclosure is not limited thereto. A plurality of transmission regions R1 and a plurality of non-transmission regions R2 may be defined by the plurality of light shielding patterns 143. The transmission region R1 has no light shielding pattern 143, and the non-transmission region R2 has the light shielding pattern 143.

When a region exposed by light is a first region 131, and a region not exposed by light, that is, a region other than the first region 131 is a second region 133, as light is applied to the photoresist layer 130, acid is diffused in the first region 131 of the photoresist layer 130. Accordingly, the benzooxazine monomer constituting the photoresist layer 130 may be photopolymerized in the presence of an acid catalyst in the first region 131. The photopolymerization in the presence of the acid catalyst may be expressed as in Chemical Rection 2.

The difference in solubility of the photoresist layer 130 may be made in the first region 131 and the second region 133 depending on the photopolymerization after the exposure process. The photoresist layer 130 of the first region 131 is photopolymerized to remarkably reduce the solubility for the developer thereafter. In some embodiments, the benzooxazine monomer is maintained without change in the photoresist layer 130 of the second region 133, thereby showing great solubility for the developer. The benzooxazine monomer may have a higher solubility for the developer to prevent defects from being caused by residues remaining after the development process, in the photolithography process, or to reduce defects.

In addition, the exposed portion (that is, the first region 131) of the photoresist layer 130 may include a crosslinked structure as shown in Chemical Reaction 2, thereby increasing the etch resistance of the first region 131 of the photoresist layer 130.

In this case, since both the material forming the underlayer 120 and the material forming the photoresist layer 130 include benzooxazine compounds, crosslinking may be easily made on the interface between the underlayer 120 and the photoresist layer 130 of the first region 131. Accordingly, the adhesion force between the photoresist layer 130 of the first region 131 and the underlayer 120 may be increased. In addition, the photoresist layer 130 of the first region 131 may be easily fixed on the underlayer 120 through chemical bonding with the underlayer 120. The increase in adhesion between the photoresist layer 130 and the underlayer 120 may suppress the collapse of the photoresist pattern, thereby increasing the patterning stability of the underlayer 120 and the feature layer 110, under the photoresist layer 130. Alternatively, an additional annealing process (e.g., baking process) to fix the photoresist layer 130 on the underlayer 120 may be omitted.

Referring to FIGS. 1 and 2D, the first region 131 of the photoresist layer 130 is removed using the developer, thereby forming a photoresist pattern 130p.

After the exposure process, the photomask 140 may be removed. The development process may be performed on the exposed photoresist layer 130. The development process may include removing the second region 133 of the photoresist layer 130 using a base developer or through a dry etching process. The base developer may include, for example, tetramethylammonium hydroxide (TMAH) and/or tetrabutylammonium hydroxide (TBAH). The second region 133 of the photoresist layer 130 may be selectively removed through the development process. The photoresist layer 130 of the first region 131 after the photoresist layer 130 of the second region 133 is removed, may be referred to as the photoresist pattern 130p. The photoresist pattern 130p may be a negative tone pattern for removing the unexposed portion.

Referring to FIGS. 1 and 2E, the underlayer 120 and the feature layer 110 may be processed using the photoresist pattern 130p.

The processing of the underlayer 120 and the feature layer 110 may include etching the underlayer 120 and the feature layer 110. The underlayer 120 and the feature layer 110 may be etched using the photoresist pattern 130p as an etching mask to form an underlayer pattern 120p and a feature layer pattern 110p. The underlayer 120 and the feature layer 110 may be etched by a wet or dry etching process, for example.

In this case, the underlayer 120 and the feature layer 110 may be simultaneously etched using the photoresist pattern 130p as the etching mask. Alternatively, the underlayer 120 is first etched by using the photoresist pattern 130p as the etching mask, and then a remaining portion of the underlayer 120 is used as the etching mask to etch the feature layer 110. FIG. 2E illustrates etching the feature layer 110 using the remaining portion of the underlayer 120 as an etching mask.

Referring to FIGS. 1 and 2F, the remaining portion of the underlayer 120 may be removed after etching the feature layer 110.

According to other embodiments, the process of forming the feature layer may be omitted, which is different from the above description. In this case, the substrate may be processed by using the photoresist pattern and the underlayer. For example, various processes may be performed, which include a process of etching a portion of the substrate by using the photoresist pattern, a process of implanting impurity ions into a partial region of the substrate, forming an additional layer on the substrate through the opening, and a process of modifying a portion of the substrate through the opening.

Embodiments of the present disclosure provide methods for fabricating the semiconductor device, capable of reducing or preventing defects resulting from the residues of the resist layer.

Although an embodiment of the present disclosure has been described for illustrative purposes, those skilled in the art will appreciate that various modifications, and substitutions are possible, without departing from the scope and spirit of the present disclosure as disclosed in the accompanying claims.

Accordingly, the technical scope of the inventive concept is not limited to the detailed description of this specification, but should be defined by the claims.

Embodiments of the present disclosure provide the resist composition for the underlayer used for the method for fabricating the semiconductor device.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method for fabricating a semiconductor device, the method comprising:
forming an underlayer on a feature layer;
forming a photoresist layer on the underlayer;
exposing a first region of the photoresist layer;
removing a second region of the photoresist layer using a developer to form a photoresist pattern while retaining the first region of the photoresist layer; and
processing the underlayer and the feature layer using the photoresist pattern,
wherein each of the underlayer and the photoresist layer comprises:
at least one of a benzooxazine monomer or a polymer produced by polymerizing the benzooxazine monomer.

2. The method of claim 1, wherein the forming of the underlayer comprises:
coating a first resist composition onto the feature layer, the first resist composition comprising the benzooxazine monomer and a solvent; and
thermally curing the first resist composition.

3. The method of claim 2, wherein the benzooxazine monomer included in the first resist composition includes:
at least one compound of Chemical Formula 1, 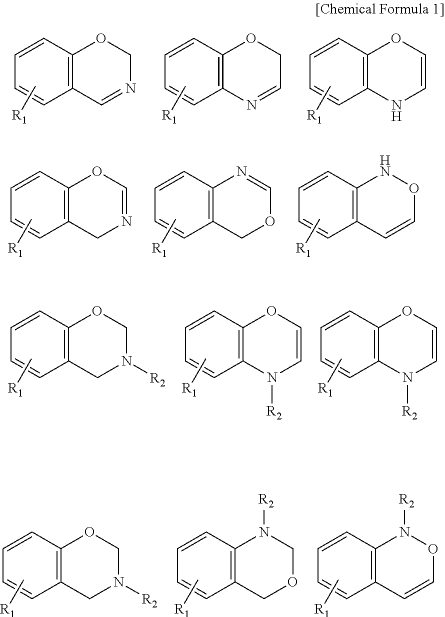
in which R₁ is at least one of a hydrogen atom, a substituted or unsubstituted monovalent hydrocarbon having 1 to 20 carbon atoms, or a halogen atom, and R₂ is a hydrogen atom, or a substituted or unsubstituted monovalent hydrocarbon having 1 to 20 carbon atoms.

4. The method of claim 3, wherein each of R₁ and R₂ is independently a functional group of Chemical Formula 2, 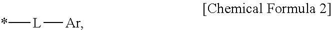
in which L is a single bond or a divalent linker, Ar is a monovalent group having an aromatic ring having 6 to 20 ring forming atoms, and * is an attaching position.

5. The method of claim 4, wherein Ar is at least one type of functional group of Chemical Formula 3,

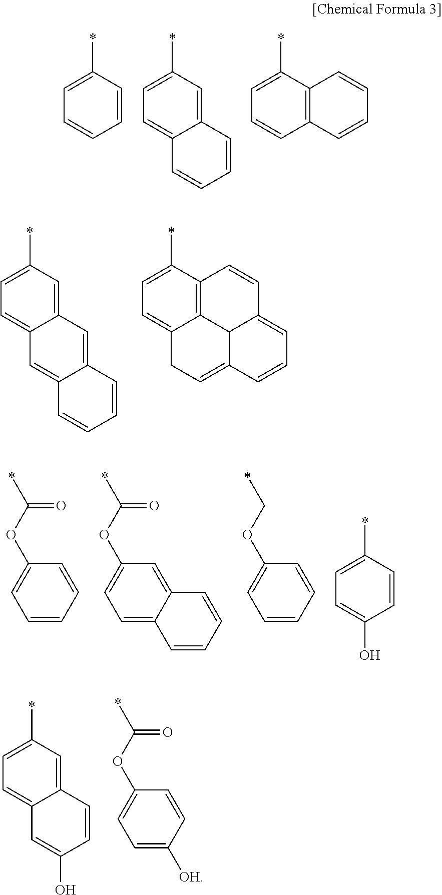

6. The method of claim 3, wherein the first resist composition further comprises:
a crosslinker.

7. The method of claim 6, wherein the crosslinker is at least one selected from polyfunctional (meth)acrylates, cyclic ether-containing compounds, glycolurils, diisocyanates, melamines, benzoguanamines, polynuclear phenols, polyfunctional thiol compounds, polysulfide compounds, and sulfide compounds.

8. The method of claim 2, wherein the forming of the photoresist layer comprises:
coating a second resist composition onto the underlayer, the second resist composition comprising the benzooxazine monomer, a photoacid generator, and a solvent.

9. The method of claim 8, wherein the benzooxazine monomer in the second resist composition comprises:
at least one type of compound of Chemical Formula 1, 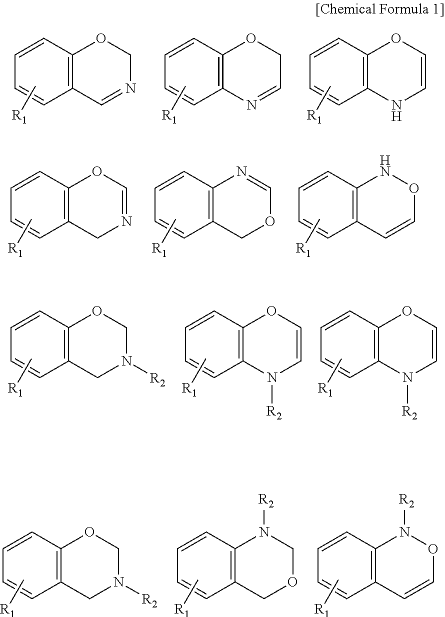
in which R₁ is at least one of a hydrogen atom, a substituted or unsubstituted monovalent hydrocarbon having 1 to 20 carbon atoms, a halogen atom, or a protecting group including an acid-labile reactor and R₂ is a hydrogen atom, or a substituted or unsubstituted monovalent hydrocarbon having 1 to 20 carbon atoms.

10. The method of claim 9, wherein each of R₁ and R₂ is independently a functional group of Chemical Formula 2, 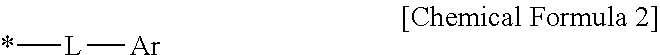
in which L is a single bond or a divalent linker, Ar is a monovalent group having an aromatic ring having 6 to 20 ring forming atoms, and * is an attaching position.

11. The method of claim 10, wherein Ar is at least one functional group of Chemical Formula 3,

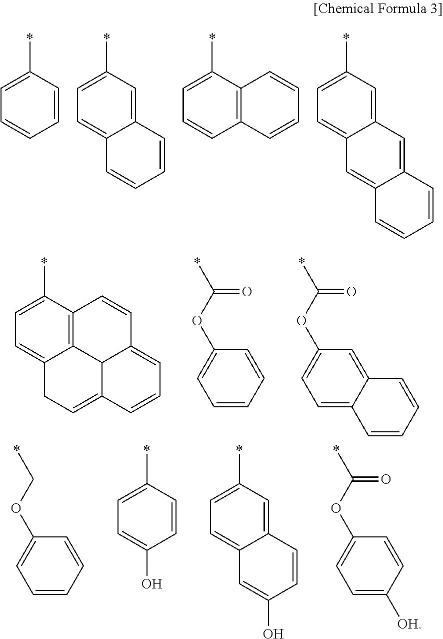

12. The method of claim 8, wherein the photoacid generator comprises:
triarylsulfonium salts, diaryliodonium salts, sulfonates or a mixture of the triarylsulfonium salts, the diaryliodonium salts, sulfonates, a mixture of triarylsulfonium salts, diaryliodonium salts, sulfonates or a mixture of the triarylsulfonium salts, the diaryliodonium salts, or sulfonates.

13. The method of claim 8, wherein the second resist composition further comprises:
a base quencher.

14. The method of claim 13, wherein the base quencher is at least one of primary aliphatic amine, secondary aliphatic amine, tertiary aliphatic amine, aromatic amine, heterocyclic ring-containing amine, nitrogen-containing compound having a carboxyl, a nitrogen-containing compound having a sulfonyl, a nitrogen-containing compound having a hydroxyl, a nitrogen-containing compound having a hydroxyphenyl, an alcoholic nitrogen-containing compound, amides, imides, carbamates, or ammonium salts.

15. The method of claim 8, wherein the second resist composition further comprises:
a crosslinker.

16. The method of claim 15, wherein the crosslinker is at least one selected from polyfunctional (meth)acrylates, cyclic ether-containing compounds, glycolurils, diisocyanates, melamines, benzoguanamines, polynuclear phenols, polyfunctional thiol compounds, polysulfide compounds, and sulfide compounds.

17. A resist composition for an underlayer, the resist composition comprising:
a benzooxazine monomer of Chemical Formula 1; and
a solvent, 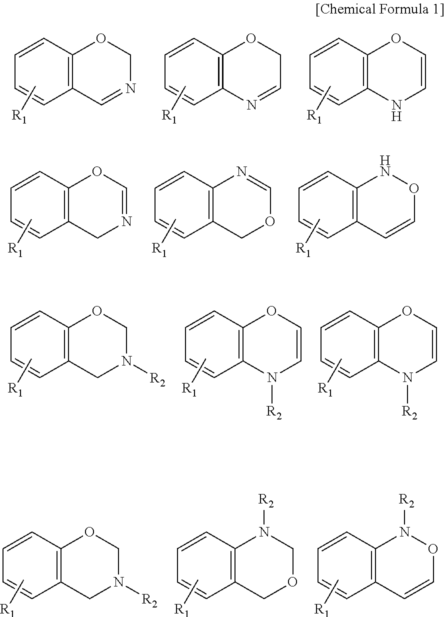
in which R₁ is at least one of a hydrogen atom, a substituted or unsubstituted monovalent hydrocarbon having 1 to 20 carbon atoms, or a halogen atom, and R₂ is a hydrogen atom, or a substituted or unsubstituted monovalent hydrocarbon having 1 to 20 carbon atoms.

18. The resist composition of claim 17, wherein each of R₁ and R₂ is independently a functional group expressed as in Chemical Formula 2, 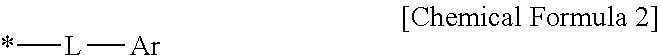
in which L is a single bond or a divalent linker, Ar is a monovalent group having an aromatic ring having 6 to 20 ring forming atoms, and ‘*’ is an attaching position.

19. The resist composition of claim 18, wherein Ar is at least one functional group of Chemical Formula 3,

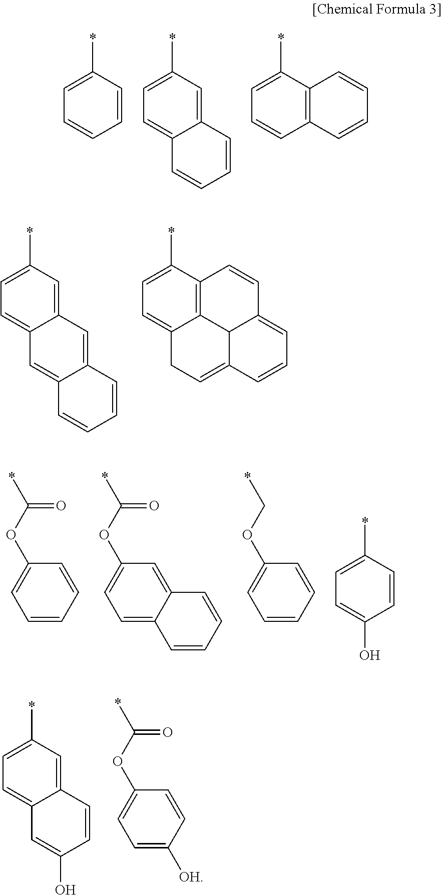

20. The resist composition of claim 17, wherein the solvent comprises at least one of ether, alcohol, glycol ether, an aromatic hydrocarbon compound, ketone, or ester.
